(19) United States
(12) Patent Application Publication
(10) Pub. No.: US 2025/0181796 A1
(43) Pub. Date: Jun. 5, 2025

(54) DESIGN METHOD AND PROGRAM

(71) Applicant: Panasonic Intellectual Property Management Co., Ltd., Osaka (JP)

(72) Inventors: Jiangpeng YU, Osaka (JP); Fei LIU, Osaka (JP); Hirofumi KUBOTA, Osaka (JP)

(21) Appl. No.: 18/844,615

(22) PCT Filed: Feb. 16, 2023
(86) PCT No.: PCT/JP2023/005425

§ 371 Date: Sep. 6, 2024

(30) Foreign Application Priority Data
Mar. 8, 2022 (JP) 2022-035468

(51) Int. Cl. G06F 30/20; G06F 30/12; G06F 30/13

(52) U.S. Cl. CPC G06F 30/20; G06F 30/12; G06F 30/13

(57) ABSTRACT

A first acquisition step includes acquiring model data of a space. A second acquisition step includes acquiring user information. The user information is information about a user's predicted mean vote with respect to the space. A third acquisition step includes acquiring candidate information presenting a candidate for an installation position. An analysis step includes analyzing, based on the model data and the user information, a distribution of the user's predicted mean vote with respect to the space when the air conditioning equipment is installed at the candidate. A determination step includes determining, when the distribution of the user's predicted mean vote with respect to the space satisfies a predetermined condition, the candidate to be the installation position.

### TECHNICAL FIELD

The present disclosure generally relates to a design method and a program. More particularly, the present disclosure relates to a design method and program for determining the installation position of air conditioning equipment.

### BACKGROUND ART

Patent Literature 1 discloses a technique for presenting a proposed installation position of an air conditioner (air conditioning equipment) to the user. Specifically, Patent Literature 1 discloses an air conditioner purchase help system including a search means, a data output means, a preferred position input means, and a propriety information transmission means. The search means searches suitable installation position information in accordance with installation room information provided by the user about the installation of an air conditioner. The data output means transmits, to the user, the suitable installation position information data searched for by the search means. The preferred position input means prompts, if the user is not satisfied with the suitable installation position data of the air conditioner which has been presented to him or her, the user to enter his or her preferred installation position. The propriety information transmission means transmits, based on the data about the user's preferred installation position which has been entered via the preferred position input means, suitable installation position data and propriety information data with respect to that installation position, both of which are stored in advance in a database, to the user.

The air conditioner purchase help system of Patent Literature 1, having such a configuration, may contribute to increasing the degree of comfort in a given space.

### CITATION LIST

### Patent Literature

Patent Literature 1: JP 2002-150051 A

### SUMMARY OF INVENTION

An object of the present disclosure is to provide a design method and program, both contributing to further increasing the degree of comfort in a given space.

A design method according to an aspect of the present disclosure is a design method for determining an installation position in a space. The installation position is a position where air conditioning equipment is to be installed. The design method includes a first acquisition step, a second acquisition step, a third acquisition step, an analysis step, and a determination step. The first acquisition step includes acquiring model data of the space. The second acquisition step includes acquiring user information. The user information is information about a user's predicted mean vote with respect to the space. The third acquisition step includes acquiring candidate information presenting a candidate for the installation position. The analysis step includes analyzing, based on the model data and the user information, a distribution of the user's predicted mean vote with respect to the space when the air conditioning equipment is installed at the candidate. The determination step includes determining, when the distribution of the user's predicted mean vote with respect to the space satisfies a predetermined condition, the candidate to be the installation position.

A program according to another aspect of the present disclosure is designed to cause one or more processors of a computer system to perform the design method described above.

### BRIEF DESCRIPTION OF DRAWINGS

FIG. 1 is a flowchart showing the procedure of a design method according to an exemplary embodiment;

FIG. 2 is a flowchart showing a detailed procedure of the processing of determining an installation position according to the design method:

FIG. 3 is a block diagram of a design system for implementing the design method:

FIG. 4 shows model data representing a space to which the design method is applied:

FIG. 5 schematically shows a PMV distribution calculated by the design method:

FIG. 6 is a graph showing the comfort rate calculated by the design method:

FIG. 7 shows model data representing a space to which the design method is applied; and

FIG. 8 shows model data representing a space to which a design method according to a first variation is applied.

### DESCRIPTION OF EMBODIMENTS

A design method according to an exemplary embodiment will now be described with reference to the accompanying drawings. Note that the exemplary embodiment to be described below is only an exemplary one of various embodiments of the present disclosure and should not be construed as limiting. Rather, the exemplary embodiment may be readily modified in various manners depending on a design choice or any other factor without departing from the scope of the present disclosure. The drawings to be referred to in the following description of embodiments are all schematic representations. Thus, the ratio of the dimensions (including thicknesses) of respective constituent elements illustrated on the drawings does not always reflect their actual dimensional ratio.

### Embodiment

### Overview

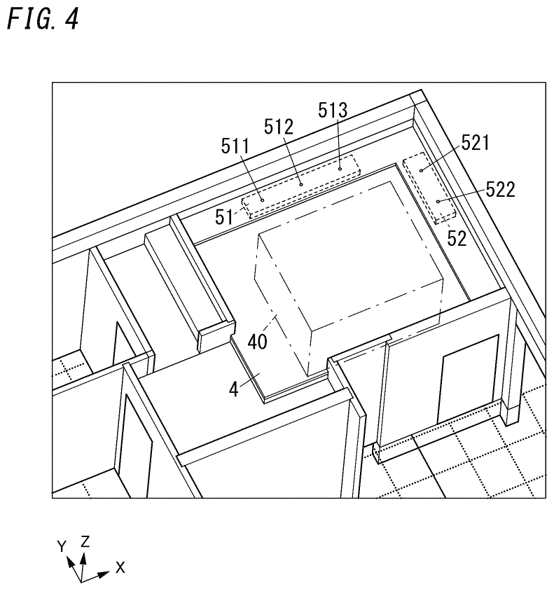

A design method according to an exemplary embodiment is a method for determining the installation position of air conditioning equipment. In particular, the design method is a method for determining, using, as an index, the predicted mean vote (PMV) of a space 4 (refer to FIG. 4) to be air-conditioned by the air conditioning equipment, the installation position of the air conditioning equipment to increase the degree of comfort in the space 4.

In the following description of embodiments, the air conditioning equipment is supposed to be an air conditioner as an example.

The space 4 is a space which forms at least part of a facility. Examples of the facility include dwelling houses, office buildings, factories, complex commercial facilities, libraries, art museums, museums, amusement facilities, airports, railway stations, hotels, nursing care facilities, and hospitals. Alternatively, the facility may also be a moving vehicle such as watercraft, a railway train, or aircraft.

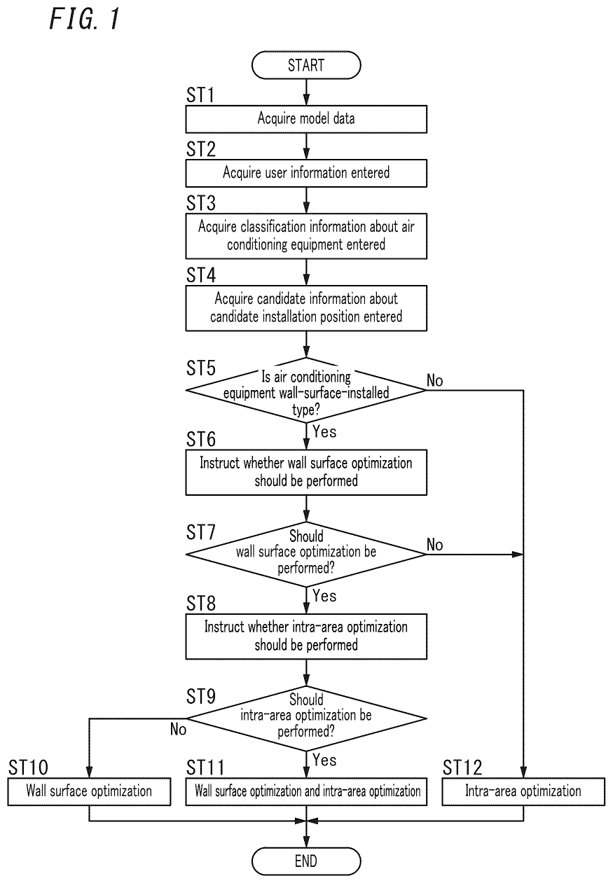

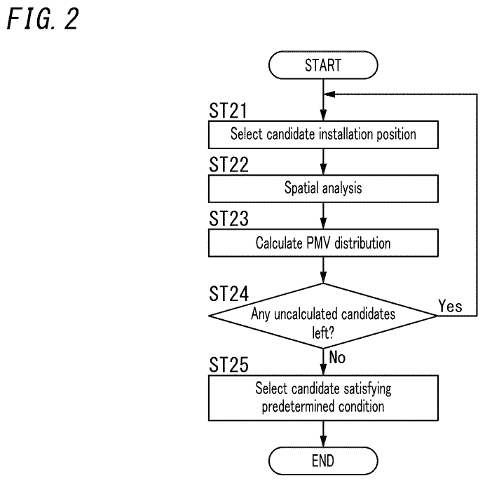

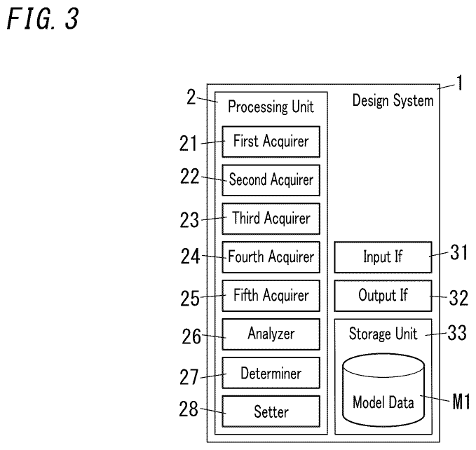

A design method according to this embodiment is a design method for determining an installation position in a space 4. The installation position is a position where air conditioning equipment is to be installed. As shown in FIGS. 1 and 2, the design method includes a first acquisition step (Step ST1), a second acquisition step (Step ST2), a third acquisition step (Step ST4), an analysis step (Step ST23), and a determination step (Step ST25). The first acquisition step (Step ST1) includes acquiring model data M1 (refer to FIG. 3) of the space 4. FIG. 4 shows an example of the model data M1 of the space 4. The second acquisition step (Step ST2) includes acquiring user information. The user information is information about a user's predicted mean vote with respect to the space 4. The third acquisition step (Step ST4) includes acquiring candidate information presenting a candidate for the installation position. The analysis step (Step ST23) includes analyzing, based on the model data M1 and the user information, a distribution of the user's predicted mean vote with respect to the space 4 when the air conditioning equipment is installed at the candidate. The determination step (Step ST25) includes determining, when the distribution of the user's predicted mean vote with respect to the space 4 satisfies a predetermined condition, the candidate to be the installation position.

This embodiment allows the installation position of the air conditioning equipment to be determined based on the distribution of the PMV, thus contributing to increasing the degree of comfort in the space 4. An installation position suitable for an individual user's properties may be determined by reference to the distribution of the PMV (hereinafter referred to as a “PMV distribution”). Note that the “user” as used herein refers to a person who is referred to as an index when the PMV is calculated.

Note that the flowcharts shown in FIGS. 1 and 2 show just an exemplary design method according to the present disclosure. Thus, the processing steps shown in FIGS. 1 and 2 may be performed in a different order as appropriate, an additional processing step may be performed as needed, or at least one of the processing steps shown there may be omitted as appropriate.

Optionally, the design method may also be implemented as a program. A program according to this embodiment is designed to cause one or more processors of a computer system to perform the design method according to this embodiment. The program may be stored in a computer-readable non-transitory storage medium.

### (Details)

### (1) Overall Configuration

A design method according to this embodiment will now be described in further detail. The design method according to this embodiment is performed by a design system 1 as shown in FIG. 3. The design system 1 includes a computer system including one or more processors and a memory. At least some of the functions of the design system 1 and the agent that performs the design method are performed by making the processor of the computer system execute a program stored in the memory of the computer system. The program may be stored in the memory. Alternatively, the program may also be downloaded via a telecommunications line such as the Internet or distributed after having been stored in a non-transitory storage medium such as a memory card.

The computer system of the design system 1 may be, for example, a personal computer, a server computer, or a tablet computer.

The design system 1 includes a processing unit 2, an input interface (IF) 31, an output interface (IF) 32, and a storage unit 33. The processing unit 2 includes the processor.

The processing unit 2 includes a first acquirer 21, a second acquirer 22, a third acquirer 23, a fourth acquirer 24, a fifth acquirer 25, an analyzer 26, a determiner 27, and a setter 28. These constituent elements just represent the respective functions to be performed by the processing unit 2 and do not necessarily have a substantive configuration.

The input IF 31 may include, for example, a pointing device such as a mouse or a touchscreen panel. The input IF 31 accepts an operating command entered by a person. The person who operates the input IF 31 may be the user or any other person, whichever is appropriate. In the following description of embodiments, the user is supposed to operate the input IF 31.

The output IF 32 may include, for example, a display. The output IF 32 presents information. More specifically, the output IF 32 presents information visually. In other words, the output IF 32 displays the information. Alternatively, the output IF 32 may also present the information as a sound (which may be a voice).

The storage unit 33 stores information. For example, the storage unit 33 stores model data M1 of the space 4.

### (2) Model Data

The first acquirer 21 acquires the model data M1 of the space 4. For example, the first acquirer 21 may acquire the model data M1 stored in the storage unit 33. Alternatively, the first acquirer 21 may also acquire the model data M1 from an external device (such as a data server) provided outside the design system 1. The model data M1 may be, for example, three-dimensional model data such as building information modeling (BIM) data.

### (3) User Information

The second acquirer 22 acquires user information. As used herein, the user information refers to information about the user's predicted mean vote (PMV) with respect to the space 4. The user information is used when the design system 1 calculates the PMV. For example, the user information may be entered into the input IF 31 by the user operating the input IF 31 and the second acquirer 22 acquires the user information from the input IF 31.

The user information includes, for example, information about the user's metabolic equivalent and the user's amount of clothing.

The user's metabolic equivalent is determined by, for example, the status of his or her activity. In other words, the user's metabolic equivalent may be determined by, for example, the type of the activity being performed by the user in the space 4. Examples of the types of activity include having a seat, walking, sleeping, and doing various sports. In this embodiment, the type of the activity being performed by the user in the space 4, for example, may be entered into the input IF 31. More specifically, a list of types of activity is displayed on the output IF 32 to let the user choose, from the list, a type of activity that he or she is going to perform. In addition, the storage unit 33 stores information representing the relationship between the types of activity and the metabolic equivalents. The information representing the relationship between the types of activity and the metabolic equivalents may be, for example, a data table. The design system 1 determines, by reference to the information representing the relationship between the types of activity and the metabolic equivalents, the metabolic equivalent based on the type of activity chosen by the user.

The user's amount of clothing (clo value) may be determined by, for example, the type of the clothes that he or she wears. Also, if the user is sleeping, the user's amount of clothing is determined by the type of the clothes that he or she wears and the type of the bedclothes that he or she uses. Thus, the type of the clothes that the user wears and the type of the bedclothes that he or she uses, for example, may be entered into the input IF 31. More specifically, a list of the types of clothes and a list of types of bedclothes are displayed on the output IF 32 to let the user choose, from the lists, a type of clothes he or she wants to wear and a type of bedclothes he or she wants to use. In addition, the storage unit 33 also stores information indicating the relationships between the respective types of clothes and bedclothes and the amount of clothing. The information indicating the relationships between the respective types of clothes and bedclothes and the amount of clothing may be, for example, a data table and a calculating formula. The design system 1 determines, by reference to the information indicating the relationships between the respective types of clothes and bedclothes and the amount of clothing, the amount of clothing based on the types of the clothes and bedclothes chosen by the user.

The user may choose the clothes to wear on a body part basis, for example. For example, as options of clothes to cover the upper body, long-sleeve clothes, short-sleeve clothes, tank tops, and no clothes are presented. As options of clothes to cover the lower body, trousers, shorts, and no clothes are presented.

In addition, the user may choose the bedclothes to use on the basis of large categories of bedclothes, for example. As options of bedclothes (comforters) to cover the user's body from over him or her, blankets made of toweling, thin and lightweight comforters, duvets, blankets, other types of comforters, and no bedclothes are presented. As options of bedclothes to be laid under the user's body, a sleeping mat, a mattress, and other types of bedclothes are presented.

On the other hand, if the user is sleeping, the user's amount of clothing is determined by not only the type of the clothes he or she wears and the type of the bedclothes he or she uses but also his or her body part covered with the bedclothes and his or her sleep posture as well. Thus, the user chooses his or her body part to be covered with the bedclothes and his or her sleep posture as well. For example, as options of body parts to be covered with the bedclothes (comforters) from over him or her, parts under the face, parts under the breast, and only the stomach are presented. As options of the sleep postures, sleeping on his or her back, sleeping on his or her side, and sleeping on his or her stomach are presented.

In association with an answer to each of these options about the clothes and bedclothes, the amounts of clothing of the clothes and bedclothes are stored in the storage device 33. The amounts of clothing of the clothes and bedclothes have been obtained in advance by measuring the quantity of heat generated using a thermal mannequin, for example.

As for the options of the body parts to be covered with the bedclothes (comforters) from over the user's body, a first coefficient to be multiplied by the amount of clothing of the bedclothes is stored in the storage unit 33. The broader the range of the body to be covered with the bedclothes is, the larger the first coefficient is. As for the options of the sleep postures, a second coefficient to be multiplied by the amount of clothing of the bedclothes to be laid under the user's body is stored in the storage unit 33. The more significantly the sleep posture increases the area of contact between the bedclothes and the user, the larger the second coefficient is.

The design system 1 may calculate, for example, the sum of the amounts of clothing of the respective answers as the user's amount of clothing. Specifically, the design system 1 calculates, by the following Equation (1), the amount of clothing (CLO_TTL1) for the period in which the user is sleeping:

$$CLO\_TTL 1 = CLO\_TOP + CLO\_DWN + CLO\_UND + ( BED\_TOP \times BED\_HTW ) + ( BED\_DWN \times BED\_POS ) \qquad ( 1 )$$

where CLO_TOP is the amount of clothing of the clothes that covers the upper body, CLO_DWN is the amount of clothing of the clothes that covers the lower body, CLO_UND is the amount of clothing of underwear (which may be a constant value irrespective of the user's input), BED_TOP is the amount of clothing of the bedclothes that covers the user's body from over him or her, BED_HTW is the first coefficient, BED_DWN is the amount of clothing of the bedclothes to be laid under the user's body, and BED_POS is the second coefficient.

Also, as a specific example, the design system 1 calculates, by the following Equation (2), the amount of clothing (CLO_TTL2) for the timing when the user wakes up (i.e., a period in which he or she is not sleeping):

$$CLO\_TTL 2 = CLO\_TOP + CLO\_DWN + CLO\_UND + CLO\_AIR \qquad ( 2 )$$

where CLO_AIR is the value of the thermal resistance between the skin and the air. CLO_AIR is a constant value irrespective of the user's input, for example.

Note that as for the bedclothes to cover the user's body from over him or her, the user's answer may be multiple types of bedclothes. If multiple types of bedclothes are his or her answer, the design system 1 calculates the user's amount of clothing based on the respective amounts of clothing of the multiple types of bedclothes. In that case, in Equations (1) and (2), for example, BED_TOP (i.e., the amount of clothing of the bedclothes that covers the user's body from over him or her) may be the sum of the amounts of clothing of the respective types of bedclothes.

### (4) Candidate Information

The third acquirer 23 acquires candidate information. As used herein, the candidate information refers to a piece of information presenting candidates for the installation position. For example, the candidate information may be entered into the input IF 31 by letting the user operate the input IF 31 and the third acquirer 23 acquires the candidate information from the input IF 31.

The candidate information may include area information. As used herein, the area information refers to a piece of information indicating one or more areas included in the space 4. The design system 1 may regard a plurality of positions within the one or more areas as respective candidates. In that case, letting the user operate the input IF 31 to designate one or more areas corresponds to entering the candidate information. For example, the user may enter the candidate information by setting the boundary with respect to each of the one or more areas.

In the example shown in FIG. 4, shown are two areas 51, 52 indicated by the area information. The area 51 includes three candidates 511, 512, 513 for the installation position. The area 52 includes two candidates 521, 522 for the installation position. The candidates 511, 512, 513 are arranged side by side in a first axial direction (X-axis direction) aligned with a horizontal plane. The candidates 521, 522 are arranged side by side in a second axial direction (Y-axis direction) aligned with the horizontal plane.

The respective positions of the candidates 511, 512, 513 are determined following a predetermined rule. For example, the respective positions of the candidates 511, 512, 513 are determined to make the gap distance between two adjacent candidates a predetermined distance (of 1 meter, for example). The respective positions of the candidates 521, 522 are also determined following a predetermined rule.

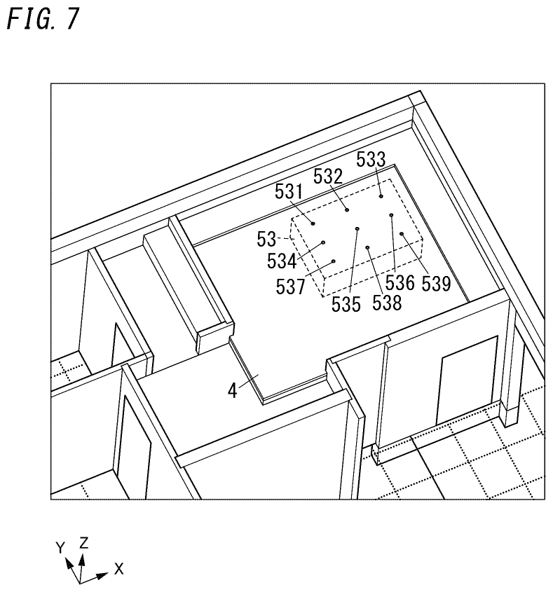

In the example shown in FIG. 7, shown is a single area 53 indicated by the area information. The area 53 includes nine candidates 531-539 for the installation position. These candidates 531-539 are arranged side by side on a single plane aligned with the horizontal plane.

The respective positions of the candidates 531-539 are determined following a predetermined rule. For example, the respective positions of the candidates 531-539 may be determined to make the gap distance between two candidates which are adjacent to each other in the X-axis direction a predetermined distance (of 1 meter, for example) and to make the gap distance between two candidates which are adjacent to each other in the Y-axis direction a predetermined distance (of 1 meter, for example).

Note that the number of candidates included in each of these areas 51, 52, 53 is not limited to the number given as an example. Rather, the number of candidates included in each area has only to be at least one. The number of candidates included in each area is preferably two or more.

To determine the installation position of the air conditioning equipment, first, the PMV distribution in the space 4 may be obtained with any one of the candidates supposed to be the installation position of the air conditioning equipment. Next, the PMV distribution in the space 4 may be obtained with another one of the candidates supposed to be the installation position of the air conditioning equipment. This series of processing steps are performed on every candidate.

In the example shown in FIG. 4 and in the example shown in FIG. 7, the plurality of candidates included in a single area have mutually discontinuous coordinates. Alternatively, the plurality of candidates may also have continuous coordinates. That is to say, to determine the installation position of the air conditioning equipment, first, the PMV distribution in the space 4 may be obtained with any one of the candidates within the area supposed to be the installation position of the air conditioning equipment. Next, the PMV distribution in the space 4 may be obtained with the installation position within the area shifted by unit distance (minimum distance). This series of processing steps may be performed repeatedly.

### (5) Classification Information

The fourth acquirer 24 acquires classification information. As used herein, the classification information refers to a piece of information about the class of the air conditioning equipment. For example, the classification information is entered into the input IF 31 by letting the user operate the input IF 31 and the fourth acquirer 24 acquires the classification information from the input IF 31. That is to say, the setting method according to this embodiment includes a class setting step including accepting the user's operating command to enter the classification information. The classification information may include the product number of the air conditioning equipment. Alternatively, the classification information may include a category larger than the product number, e.g., whether the air conditioning equipment is a ceiling-embedded type and whether the air conditioning equipment is a wall-mounted type.

The classification information may include, for example, a piece of information for use to determine whether the air conditioning equipment is a wall-surface-installed type. As used herein, the wall-surface-installed air conditioning equipment refers to air conditioning equipment, such as wall-mounted air conditioning equipment, which is installed either on, or in the vicinity of, the wall surface. More specifically, a list of classes of the air conditioning equipment is displayed on the output IF 32 to let the user choose, from the list, a class of air conditioning equipment that he or she wants to install. In addition, the storage unit 33 also stores information indicating whether each class of the air conditioning equipment corresponds to the wall-surface-installed type. The design system 1 determines, by reference to the information stored in the storage unit 33, whether the class of the air conditioning equipment which has been entered into the input IF 31 corresponds to the wall-surface-installed type.

As used herein, the “wall surface” refers to a surface intersecting with the horizontal plane. A vertical surface provided for a step portion of a coved ceiling also corresponds to the “wall surface.” Furthermore, the air conditioning equipment installed to be embedded in the step portion of the coved ceiling corresponds to the wall-surface-installed type.

Meanwhile, air conditioning equipment which may be embedded in the ceiling to be installed away from, or in the vicinity of, the wall surface does not correspond to the wall-surface-installed type.

### (6) Target Space Information

The fifth acquirer 25 acquires target space information. As used herein, the target space information refers to a piece of information defining the range of the target space 40 (refer to FIG. 4). The target space 40 is a target space where the PMV is supposed to be controlled. The target space 40 forms part of the space 4. The space 4 may be, for example, a single room. The distance from the target space 40 to the wall of the room varies depending on from which one of a plurality of points in the target space 40 the distance is measured. When a point that makes the distance shortest is taken, the shortest distance may be, for example, a predetermined distance (of 1 meter, for example). Also, the vertical distance from any point in the target space 40 to the floor of the room may fall, for example, within a predetermined range (e.g., equal to or longer than 0.1 meters and equal to or shorter than 1.7 meters).

For example, the target space information may be entered into the input IF 31 by letting the user operate the input IF 31 and the fifth acquirer 25 acquires the target space information from the input IF 31. More specifically, the user may enter the target space information by setting a boundary for the target space 40.

### (7) Analyzer

The analyzer 26 analyzes, based on the model data M1 and the user information, the PMV distribution in the space 4 in a situation where the air conditioning equipment is installed at the candidate installation position.

More specifically, first, the analyzer 26 makes, based on the model data M1, a spatial analysis on the space 4 in a situation where the air conditioning equipment is installed at the candidate installation position. The spatial analysis made by the analyzer 26 is a simulation that uses an experimental design method such as the Latin hypercube method or the Monte Carlo method. As a result of the spatial analysis, environmental information is generated. The environmental information includes information about the temperature distribution, relative humidity, air velocity, and thermal radiation temperature in the space 4. Information about the air velocity may be, for example, an average air velocity or an air velocity distribution in the space 4. The information about the thermal radiation temperature may be, for example, an average thermal radiation temperature or thermal radiation temperature distribution in the space 4.

Next, the analyzer 26 calculates the PMV distribution based on the environmental information and the user information. In this case, the environmental information includes information about the temperature distribution in the space 4. Thus, the respective PMVs at multiple points in the same space 4 may be calculated as mutually different values due to a difference in temperature, for example.

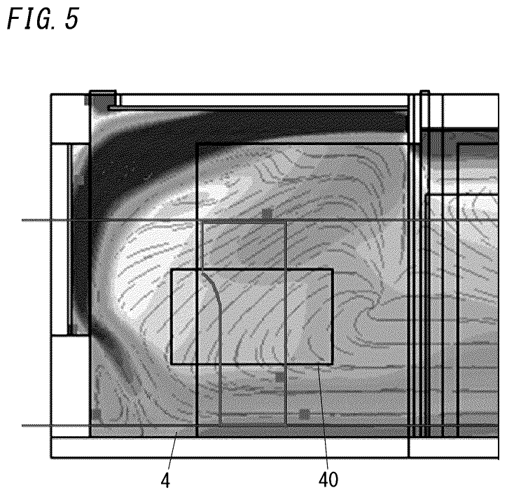

The output IF 32 preferably displays the PMV distribution calculated by the analyzer 26. The output IF 32 may display the PMV distribution by, for example, presenting the respective points in a three-dimensional image representing the space 4 in multiple different colors according to the magnitude of the PMV as shown in FIG. 5. Although the image shown in FIG. 5 is a monochrome image, it is preferable that the PMV distribution be actually displayed as a color image.

### (8) Determiner

The determiner 27 refers to the PMV distribution calculated by the analyzer 26. The determiner 27 determines whether the PMV distribution satisfies a predetermined condition or not. The determiner 27 determines the installation position of the air conditioning equipment when the PMV distribution satisfies the predetermined condition to be the final installation position and outputs the installation position thus determined.

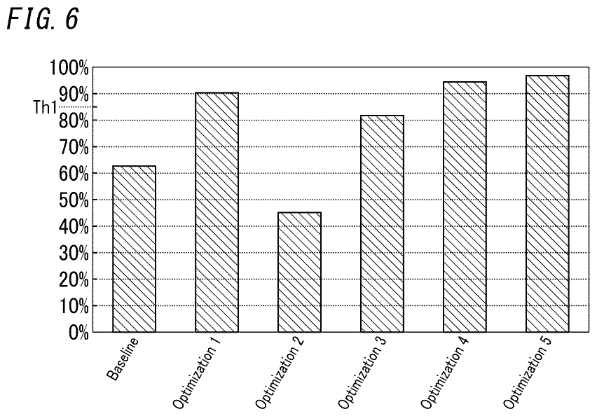

For example, the predetermined condition may include a condition that the percentage of the region where the PMV falls within a predetermined range to the predefined target space 40 belonging to the space 4 be equal to or greater than the threshold value Th1 (refer to FIG. 6). In general, the closer to zero the PMV is, the more comfortable the user may feel. Thus, the predetermined range preferably includes a point where PMV=0. In this embodiment, the predetermined range is a range where the absolute value of the PMV is equal to or less than a predetermined value. In this embodiment, the predetermined value is 0.5. That is to say, the predetermined range is a range equal to or greater than −0.5 and equal to or less than 0.5.

Note that the predetermined value does not have to be 0.5 but may also be changed as appropriate. Alternatively, the predetermined value may also be 1.0, for example.

In the following description, the percentage of the region where the PMV falls within the predetermined range to the target space 40 will be hereinafter referred to as a “comfort rate.” The comfort rate may be calculated on a volume basis or on an area basis, whichever is appropriate. If the comfort rate is calculated on a volume basis, (comfort rate)=100×(area of a region where the PMV falls within the predetermined range)/(volume of the target space 40).

FIG. 6 shows the comfort rates for the respective candidate positions where the air conditioning equipment may be installed. In FIG. 6, “Baseline” indicates the comfort rate calculated based on a PMV distribution in a state where no air conditioning equipment is installed while “Optimizations 1-5” each indicate the comfort rate calculated based on a PMV distribution in a state where the air conditioning equipment is installed. The “Optimizations 1-5” are associated with respectively different installation positions of the air conditioning equipment. Specifically, for example, a first PMV distribution is calculated by the analyzer 26 in a state where the air conditioning equipment is installed at a first installation position and the comfort rate calculated based on the first PMV distribution is approximately 90% (refer to Optimization 1). In the same way, a second PMV distribution is calculated by the analyzer 26 in a state where the air conditioning equipment is installed at a second installation position and the comfort rate calculated based on the second PMV distribution is approximately 45% (refer to Optimization 2).

The threshold value Th1 may be 85%, for example. In FIG. 6, in each of Optimizations 1, 4, and 5, the comfort rate is greater than the threshold value Th1. Thus, if the predetermined condition consists of only a condition that the comfort rate be equal to or greater than the threshold value Th1, for example, the determiner 27 determines three installation positions associated with the Optimizations 1, 4, and 5 to be final installation positions and outputs the three installation positions.

Optionally, the predetermined condition may further include a condition that the comfort rate be maximum among a plurality of candidate installation positions. In that case, the determiner 27 determines an installation position associated with the Optimization 5 to be the final installation position and outputs the installation position.

### (9) Setter

The setter 28 performs a user setting step including accepting entry about at least one of the range of the space 4, the user information, the candidate information, or the predetermined condition. More specifically, at least one of the range of the space 4, the user information, the candidate information, or the predetermined condition is entered into the input IF 31 by letting the user operate the input IF 31. In response to the entry of the parameter into the input IF 31, the setter 28 sets at least one of the range of the space 4, the user information, the candidate information, or the predetermined condition.

As used herein, the entry about the range of the space 4 may include, for example, specifying the range of the entire space 4.

The entry about the predetermined condition may include, for example, at least one of setting the threshold value Th1 or specifying the range of the target space 40.

### (10) Flow of Determining Installation Position

Next, an exemplary procedure of the design method for determining the installation position of the air conditioning equipment will be described with reference to FIGS. 1 and 2. In the following description, the predetermined condition for determining the installation position is supposed to be a condition that the comfort rate be equal to or greater than the threshold value Th1 and be maximum among a plurality of candidate installation positions.

### (10.1) Various Types of Entries

The first acquirer 21 acquires the model data M1 of the space 4 (in Step ST1). For example, the first acquirer 21 acquires the model data M1 stored in the storage unit 33.

The second acquirer 22 acquires the user information (in Step ST2). For example, the user enters the user information into the input IF 31 and the second acquirer 22 acquires the user information entered into the input IF 31.

The fourth acquirer 24 acquires the classification information (in Step ST3). For example, the user enters the classification information into the input IF 31 and the fourth acquirer 24 acquires the classification information entered into the input IF 31.

The third acquirer 23 acquires the candidate information (in Step ST4). For example, the user enters the candidate information into the input IF 31 and the third acquirer 23 acquires the candidate information entered into the input IF 31. Specifically, the user specifies one or more areas where the air conditioning equipment may be installed. The user specifies one or more areas with the design property of the space 4, the restrictions on the design, and the class of the air conditioning equipment, for example, taken into account. As used herein, “taking restrictions on the design into account” may refer to, for example, specifying one or more areas while avoiding a place where another member (such as piping) that has nothing to do with the air conditioning equipment to be installed has been installed or is going to be installed. This is because the air conditioning equipment cannot be installed in such a place. Also, as used herein, “taking the class of the air conditioning equipment into account” may refer to, for example, specifying one or more areas along the wall surface when the air conditioning equipment is a wall-mounted type or specifying one or more areas in a step portion when the air conditioning equipment is designed to be embedded in the step portion of a coved ceiling.

Next, the design system 1 determines, by reference to the classification information, whether the air conditioning equipment is the wall-surface-installed type (in Step ST5). As described above, information indicating whether the class of each air conditioning equipment corresponds to the wall-surface-installed type or not is stored in the storage unit 33. The design system 1 determines, by reference to the information stored in the storage unit 33, whether the class of the air conditioning equipment which has been entered into the input IF 31 is the wall-surface-installed type or not.

First, a situation where the class of the air conditioning equipment corresponds to the wall-surface-installed type (i.e., a situation where the answer is YES in Step ST5) will be described.

The user enters, into the input IF 31, an instruction indicating whether the wall surface optimization should be performed or not (in Step ST6). If the user instructs that the wall surface optimization should be performed (i.e., if the answer is YES in Step ST7), the process proceeds to Step ST8. On the other hand, if the user instructs that the wall surface optimization should not be performed (i.e., if the answer is NO in Step ST7), then intra-area optimization is performed as will be described later (in Step ST12).

In Step ST8, the user enters, into the input IF 31, an instruction indicating whether the intra-area optimization should be performed or not. If the user instructs that the intra-area optimization should be performed (i.e., if the answer is YES in Step ST9), then the wall surface optimization and the intra-area optimization are performed as will be described later (in Step ST11). On the other hand, if the user instructs that the intra-area optimization should not be performed (i.e., if the answer is NO in Step ST9), then the wall surface optimization is performed as will be described later (in Step ST10).

Each of Steps ST10, ST11, and ST12 is the processing step of determining the installation position. These steps ST10, ST11, and ST12 are different in one or more candidates for the installation position but include the same processing in the other respects. The processing to be performed in common in these steps ST10, ST11, and ST12 will be described with reference to FIG. 2.

First, the design system 1 selects one candidate from one or more candidates (in Step ST21). The analyzer 26 performs spatial analysis on the supposition that the air conditioning equipment has been installed at the selected candidate (in Step ST22), thereby generating environmental information about the temperature distribution in the space 4, for example. In addition, the analyzer 26 also calculates the PMV distribution based on the environmental information and the user information (in Step ST23).

Step ST24 includes determining whether the PMV distribution has been calculated with respect to every candidate. If the number of the one or more candidates is one, then the PMV distribution has already been calculated for every candidate (i.e., the answer is NO in Step ST24) and therefore, the process proceeds to Step ST25. On the other hand, if the number of the one or more candidates is two or more, the answer is YES in Step ST24, and the process returns to Step ST21 in which the design system 1 selects an unselected candidate from the two or more candidates. This series of processing steps ST21-ST24 will be performed repeatedly until the PMV distribution has been calculated with respect to every candidate.

Step ST25 includes selecting a candidate in which the PMV distribution satisfies the predetermined condition from the plurality of candidates and determining the candidate thus selected to be the installation position. The output IF 32 presents the installation position that has been determined in Step ST25.

### (10.2) Determining Installation Position of Wall-Surface-Installed Air Conditioning Equipment

As described above, if the air conditioning equipment is the wall-surface-installed type (i.e., if the answer is YES in Step ST5), then any one of Steps ST10, ST11, or ST12 is performed. This allows the installation position of the air conditioning equipment to be determined. In the following description, information that specifies the areas 51, 52 is supposed to have been entered as candidate information in Step ST4 as shown in FIG. 4.

Step ST10 (wall surface optimization) includes determining a wall surface belonging to the plurality of wall surfaces which corresponds to a PMV distribution that satisfies the predetermined condition to be the installation position of the air conditioning equipment. Specifically, the installation position of the air conditioning equipment is selected from the group consisting of a wall surface corresponding to the area 51 and a wall surface corresponding to the area 52. For example, the determiner 27 may suppose the candidate 512 to be a representative position in the area 51 and also suppose the candidate 521 to be a representative position in the area 52. The analyzer 26 calculates a PMV distribution in a situation where the air conditioning equipment is installed at the candidate 512 and a PMV distribution in a situation where the air conditioning equipment is installed at the candidate 521. The determiner 27 determines the installation position based on the respective PMV distributions of the candidates 512, 521. That is to say, the determiner 27 determines one of these candidates 512, 521, of which the PMV distribution satisfies the predetermined condition, to be the installation position.

That is to say, in the wall surface optimization, the analyzer 26 supposes each of the plurality of areas to be a candidate installation position for the air conditioning equipment to calculate the PMV distribution for the candidate area. The determiner 27 determines, by reference to the PMV distributions for the respective candidates, one of those candidates that satisfies the predetermined condition to be the installation position.

Step ST11 (wall surface optimization and intra-area optimization) includes selecting the best wall surface for installing the air conditioning equipment from a plurality of wall surfaces and determining a position located on the wall surface which corresponds to a PMV distribution that satisfies the predetermined condition to be the installation position of the air conditioning equipment. Specifically, the analyzer 26 calculates, with respect to each of the plurality of candidates 511, 512, 513 included in the area 51 and the plurality of candidates 521, 522 included in the area 52, a PMV distribution in a situation where the air conditioning equipment is installed at the candidate position. The determiner 27 determines the installation position based on the respective PMV distributions of these candidates 511, 512, 513, 521, and 522. That is to say, the determiner 27 determines any one of these candidates 511, 512, 513, 521, and 522, of which the PMV distribution satisfies the predetermined condition, to be the installation position.

That is to say, the wall surface optimization and the intra-area optimization may be performed in combination in the following manner. Specifically, each of the plurality of areas includes a plurality of candidates and the analyzer 26 calculates a PMV distribution for each of the plurality of candidates. The determiner 27 determines, by reference to the respective PMV distributions for those candidates, one of those candidates that satisfies the predetermined condition to be the installation position.

Step ST12 (intra-area optimization) includes determining a position falling within a particular wall surface (area) which corresponds to a PMV distribution that satisfies the predetermined condition to be the installation position of the air conditioning equipment. Specifically, first, the user chooses one of the areas 51, 52 by operating the input IF 31. This allows the design system 1 to exclude one or more areas from the plurality of candidate areas in accordance with the operating command entered by the user. In this example, suppose the area 51 has been chosen and the area 52 has been excluded from the candidate areas. Next, the analyzer 26 calculates, with respect to each of the plurality of candidates 511, 512, 513 included in the area 51, a PMV distribution in a situation where the air conditioning equipment is installed at the candidate position. The determiner 27 determines the installation position based on the respective PMV distributions of these candidates 511, 512, 513. That is to say, the determiner 27 determines one of these candidates 511, 512, 513, of which the PMV distribution satisfies the predetermined condition, to be the installation position.

That is to say, in the intra-area optimization, the analyzer 26 supposes each of the plurality of positions included in a predetermined area to be a candidate installation position for the air conditioning equipment to calculate the PMV distribution for the candidate. The determiner 27 determines, by reference to the PMV distributions for the respective candidates, one of those candidates that satisfies the predetermined condition to be the installation position.

Note that if the user has entered only one area in Step ST4, then the determiner 27 may determine, in Step ST12, one of the plurality of candidates included in the area which corresponds to a PMV distribution that satisfies the predetermined condition to be the installation position.

### (10.3) Determining Installation Position of Air Conditioning Equipment of Non-Wall-Surface-Installed Type

If the air conditioning equipment is non-wall-surface-installed type (i.e., if the answer to Step ST5 is NO), then Step ST12 (intra-area optimization) is performed. This allows the installation position of the air conditioning equipment to be determined. Unlike the situation where the air conditioning equipment is the wall-surface-installed type, the plurality of candidates 531-539 falling within the single area 53 are not arranged side by side in one direction but are arranged on a single plane aligned with the horizontal plane as shown in FIG. 7.

Step ST12 (intra-area optimization) includes determining a position falling within a particular area 53 which corresponds to a PMV distribution that satisfies the predetermined condition to be the installation position of the air conditioning equipment. Specifically, the analyzer 26 calculates, with respect to each of the plurality of candidates 531-539 included in the area 53, a PMV distribution in a situation where the air conditioning equipment is installed at the candidate position. The determiner 27 determines the installation position based on the respective PMV distributions of these candidates 531-539. That is to say, the determiner 27 determines one of these candidates 531-539, of which the PMV distribution satisfies the predetermined condition, to be the installation position.

Optionally, the candidates 531-539 may be distributed in a plurality of areas.

### (10.4) First Scheme and Second Scheme

As described above, the design method according to this embodiment includes determining the candidates differently depending on whether the air conditioning equipment is the wall-surface-installed type or non-wall-surface-installed type. The design method includes determining the candidates by a first scheme in the former case and determining the candidates by a second scheme in the latter case.

More specifically, the design method includes a fourth acquisition step including acquiring classification information about the class of the air conditioning equipment. The design method includes determining, according to the classification information, the scheme for determining the candidates to be either the first scheme or the second scheme.

According to the first scheme, a plurality of positions falling within each of one or more areas which have mutually different coordinates in a first axial direction aligned with the horizontal plane are determined to be respective candidates. The first axial direction in the area 51 is an X-axis direction. For example, in the area 51, three positions having mutually different coordinates in the X-axis direction are determined to be candidates 511, 512, 513. The first axial direction in the area 52 is a Y-axis direction. For example, in the area 52, two positions having mutually different coordinates in the Y-axis direction are determined to be candidates 521, 522.

According to the second scheme, a plurality of positions falling within each of one or more areas which have mutually different coordinates in at least one of a first axial direction or a second axial direction aligned with the horizontal plane are determined to be respective candidates. The first axial direction in the area 53 is an X-axis direction. The second axial direction in the area 53 is a Y-axis direction. For example, in the area 53, nine positions having mutually different coordinates in the X-axis direction and/or mutually different coordinates in the Y-axis direction are determined to be candidates 531-539.

### (11) Advantages

The design method according to this embodiment allows the installation position of air conditioning equipment to be determined according to the PMV distribution. This contributes to increasing the degree of comfort in the space 4.

In particular, the design method according to this embodiment allows, when the intra-area optimization is performed, the installation position to be adjusted to a better position within a given area. For example, the intra-area optimization may increase the comfort rate in a situation where the comfort rate would be increased by slightly shifting the position of the air conditioning equipment compared to installing the air conditioning equipment at a certain position within the area.

### (First Variation)

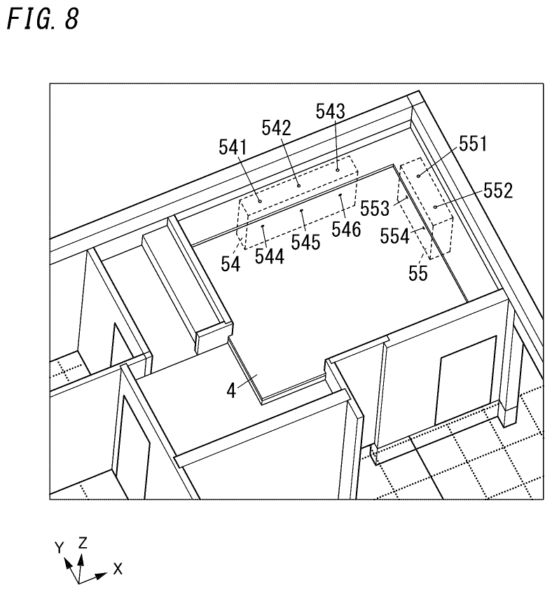

Next, a design method according to a first variation will be described with reference to FIG. 8. In the following description, any constituent element of this first variation, having the same function as a counterpart of the embodiment described above, will be designated by the same reference numeral as that counterpart's, and description thereof will be omitted herein.

This first variation is different from the exemplary embodiment described above in the method of selecting a plurality of candidates by the first scheme. The first scheme according to this first variation includes supposing, to be respective candidates, a plurality of positions having mutually different coordinates in a first axial direction and/or mutually different coordinates in a third axial direction aligned with the vertical direction within each of one or more areas.

In FIG. 8, the area 54 has a length in the X-axis direction and a length in the Z-axis direction. The first axial direction in the area 54 is the X-axis direction. The third axial direction in the area 54 is the Z-axis direction.

The area 55 has a length in the Y-axis direction and a length in the Z-axis direction. The first axial direction in the area 55 is the Y-axis direction. The third axial direction in the area 55 is the Z-axis direction.

The area 54 includes candidates 541-546. The candidates 541-543 are arranged side by side in the X-axis direction. The candidates 544-546 are also arranged side by side in the X-axis direction. The candidates 541-543 face, in the Z-axis direction, the candidates 544-546.

The area 55 includes candidates 551-554. The candidates 551, 552 are arranged side by side in the Y-axis direction. The candidates 553, 554 are also arranged side by side in the Y-axis direction. The candidates 551, 552 face, in the Z-axis direction, the candidates 553, 554.

This first variation contributes to optimizing the PMV distribution by adjusting the installation position of the air conditioning equipment in not only the direction aligned with the horizontal plane but also in the vertical direction as well.

### Other Variations of Embodiment

Next, variations of the exemplary embodiment will be enumerated one after another. Note that the variations to be described below may be adopted in combination as appropriate. Alternatively, any of the variations to be described below may also be adopted in combination with the first variation as appropriate.

In the exemplary embodiment described above, the determiner 27 determines, based on the PMV distribution, for example, only one installation position that satisfies the predetermined condition. Alternatively, the determiner 27 may also determine, based on the PMV distribution, a plurality of installation positions that satisfy the predetermined condition.

In the exemplary embodiment described above, the determiner 27 determines the installation position of the air conditioning equipment to allow the PMV distribution with respect to a single user to satisfy the predetermined condition. Alternatively, the analyzer 26 may calculate the PMV distribution with respect to each of a plurality of users and the determiner 27 may determine the installation position of the air conditioning equipment to allow the PMV distribution with respect to each of the plurality of users to satisfy the predetermined condition.

In the exemplary embodiment described above, the installation position of a single piece of air conditioning equipment to be installed in the space 4 is determined by the design method. Alternatively, the installation positions of multiple pieces of air conditioning equipment to be installed in the space 4 may be determined by the design method. For example, the processing of calculating the PMV distributions may be performed repeatedly with the installation positions of the multiple pieces of air conditioning equipment changed every time to determine the installation positions of the multiple pieces of air conditioning equipment in a situation where the PMV distributions satisfy the predetermined condition.

Optionally, the user may choose the scheme for determining candidate installation positions from the first scheme and the second scheme. That is to say, the user may choose either the first scheme or the second scheme by operating the input IF 31.

The scheme for determining candidate installation positions may be fixed at either the first scheme or the second scheme.

The plurality of candidate installation positions may be arranged one on top of another in a third axial direction aligned with the vertical direction.

The air conditioning equipment does not have to be an air conditioner but may also be, for example, a heater, a freezer, an air-conditioning duct, a blower, or ventilating equipment.

The design system 1 according to the present disclosure or the agent that performs the design method according to the present disclosure includes a computer system. The computer system may include a processor and a memory as hardware components thereof. At least some functions of the design system 1 according to the present disclosure or the agent that performs the design method according to the present disclosure may be performed by making the processor execute a program stored in the memory of the computer system. The program may be stored in advance in the memory of the computer system. Alternatively, the program may also be downloaded through a telecommunications line or be distributed after having been recorded in some non-transitory storage medium such as a memory card, an optical disc, or a hard disk drive, any of which is readable for the computer system. The processor of the computer system may be made up of a single or a plurality of electronic circuits including a semiconductor integrated circuit (IC) or a large-scale integrated circuit (LSI). As used herein, the “integrated circuit” such as an IC or an LSI is called by a different name depending on the degree of integration thereof. Examples of the integrated circuits such as an IC or an LSI include integrated circuits called a “system LSI,” a “very-large-scale integrated circuit (VLSI),” and an “ultra-large-scale integrated circuit (ULSI).” Optionally, a field-programmable gate array (FPGA) to be programmed after an LSI has been fabricated or a reconfigurable logic device allowing the connections or circuit sections inside of an LSI to be reconfigured may also be adopted as the processor. Those electronic circuits may be either integrated together on a single chip or distributed on multiple chips, whichever is appropriate. Those multiple chips may be aggregated together in a single device or distributed in multiple devices without limitation. As used herein, the “computer system” includes a microcontroller including one or more processors and one or more memories. Thus, the microcontroller may also be implemented as a single or a plurality of electronic circuits including a semiconductor integrated circuit or a large-scale integrated circuit.

Also, in the embodiment described above, the plurality of functions of the design system 1 are aggregated together in a single device. However, this is not an essential configuration for the design system 1. Alternatively, those constituent elements of the design system 1 may be distributed in multiple different devices. For example, the input IF 31 may be provided separately from the processing unit 2. Still alternatively, at least some functions of the design system 1 (e.g., some functions of the analyzer 26) may be implemented as a server or a cloud computing system as well.

### (Recapitulation)

The exemplary embodiment and its variations described above are specific implementations of the following aspects of the present disclosure.

A design method according to a first aspect is a design method for determining an installation position in a space (4). The installation position is a position where air conditioning equipment is to be installed. The design method includes a first acquisition step, a second acquisition step, a third acquisition step, an analysis step, and a determination step. The first acquisition step includes acquiring model data (M1) of the space (4). The second acquisition step includes acquiring user information. The user information is information about a user's predicted mean vote with respect to the space (4). The third acquisition step includes acquiring candidate information presenting a candidate for the installation position. The analysis step includes analyzing, based on the model data (M1) and the user information, a distribution of the user's predicted mean vote with respect to the space (4) when the air conditioning equipment is installed at the candidate. The determination step includes determining, when the distribution of the user's predicted mean vote with respect to the space (4) satisfies a predetermined condition, the candidate to be the installation position.

This method allows the installation position of air conditioning equipment to be determined according to the distribution of the predicted mean vote, thus contributing to increasing the degree of comfort in the space (4).

In a design method according to a second aspect, which may be implemented in conjunction with the first aspect, the candidate information includes area information presenting one or more areas included in the space (4). According to the design method, a plurality of positions within the one or more areas are presented as the candidates.

This method enables adjusting the installation position of the air conditioning equipment without deviating from the area.

A design method according to a third aspect, which may be implemented in conjunction with the second aspect, further includes a fourth acquisition step including acquiring classification information about a class of the air conditioning equipment. The design method includes determining, in accordance with the classification information, a scheme for determining the candidate to be either a first scheme or a second scheme. The first scheme includes setting, as the plurality of the candidates, a plurality of positions having mutually different coordinates in a first axial direction aligned with a horizontal plane, within each of the one or more areas. The second scheme includes setting, as the plurality of the candidates, a plurality of positions having mutually different coordinates in the first axial direction and/or mutually different coordinates in a second axial direction aligned with the horizontal plane, within each of the one or more areas.

This method allows the installation position of the air conditioning equipment to be adjusted by an appropriate scheme selected according to the class of the air conditioning equipment.

In a design method according to a fourth aspect, which may be implemented in conjunction with the third aspect, the first scheme includes setting, as the plurality of the candidates, a plurality of positions having mutually different coordinates in the first axial direction and/or mutually different coordinates in a third axial direction aligned with a vertical direction, within each of the one or more areas.

This method allows the installation height of the air conditioning equipment to be adjusted.

In a design method according to a fifth aspect, which may be implemented in conjunction with any one of the first to fourth aspects, the predetermined condition includes a condition that a percentage of a region where the predicted mean vote falls within a predetermined range to a predefined target space (40) belonging to the space (4) be equal to or greater than a threshold value (Th1).

This method ensures a degree of comfort in a relatively broad range within the target space (40).

A design method according to a sixth aspect, which may be implemented in conjunction with any one of the first to fifth aspects, further includes a user setting step including accepting input about at least one of a range of the space (4), the user information, the candidate information, or the predetermined condition.

This method allows the installation position of the air conditioning equipment to be determined according to the user's preference and properties (such as his or her metabolic equivalent and amount of clothing), for example.

Note that the features according to the second to sixth aspects are not essential features for the design method but may be omitted as appropriate.

A program according to a seventh aspect is designed to cause one or more processors of a computer system to perform the design method according to any one of the first to sixth aspects.

This program contributes to increasing the degree of comfort in the space (4).

Note that these are not the only aspects of the present disclosure but various configurations (including variations) of the design system (1) according to the exemplary embodiment described above may also be implemented as, for example, a design method, a (computer) program, or a non-transitory storage medium on which the program is stored.

### REFERENCE SIGNS LIST

4 Space
40 Target Space
M1 Model Data
Th1 Threshold Value

1. A design method for determining an installation position where air conditioning equipment is to be installed in a space, the design method comprising:
a first acquisition step including acquiring model data of the space;
a second acquisition step including acquiring user information about a user's predicted mean vote with respect to the space;
a third acquisition step including acquiring candidate information presenting a candidate for the installation position;
an analysis step including analyzing, based on the model data and the user information, a distribution of the user's predicted mean vote with respect to the space when the air conditioning equipment is installed at the candidate; and
a determination step including determining, when the distribution of the user's predicted mean vote with respect to the space satisfies a predetermined condition, the candidate to be the installation position.

2. The design method of claim 1, wherein
the candidate information includes area information presenting one or more areas included in the space, and
a plurality of positions within the one or more areas are presented as a plurality of the candidates.

3. The design method of claim 2, further comprising a fourth acquisition step
including acquiring classification information about a class of the air conditioning equipment,
wherein
the design method includes determining, in accordance with the classification information, a scheme for determining the candidate to be either a first scheme or a second scheme,
the first scheme includes setting, as the plurality of the candidates, a plurality of positions having mutually different coordinates in a first axial direction aligned with a horizontal plane, within each of the one or more areas, and
the second scheme includes setting, as the plurality of the candidates, a plurality of positions having mutually different coordinates in the first axial direction and/or mutually different coordinates in a second axial direction aligned with the horizontal plane, within each of the one or more areas.

4. The design method of claim 3, wherein
the first scheme includes setting, as the plurality of the candidates, a plurality of positions having mutually different coordinates in the first axial direction and/or mutually different coordinates in a third axial direction aligned with a vertical direction, within each of the one or more areas.

5. The design method of claim 1, wherein
the predetermined condition includes a condition that a percentage of a region where the predicted mean vote falls within a predetermined range to a predefined target space belonging to the space be equal to or greater than a threshold value.

6. The design method of claim 1, further comprising a user setting step including accepting input about at least one of a range of the space, the user information, the candidate information, or the predetermined condition.

7. A non-transitory storage medium recording a computer program designed to cause one or more processors of a computer system to perform the design method of claim 1.
